(19) United States
(12) Patent Application Publication
(10) Pub. No.: US 2025/0168975 A1
(43) Pub. Date: May 22, 2025

(54) CORE SUBSTRATE FOR WIRING BOARDS AND METHOD FOR PRODUCING SAME, AND WIRING BOARD AND METHOD FOR PRODUCING SAME

(71) Applicant: Resonac Corporation, Minato-ku, Tokyo (JP)

(72) Inventors: Masataka NISHIDA, Minato-ku, Tokyo (JP); Hirokazu NOMA, Minato-ku, Tokyo (JP); Masaki YAMAGUCHI, Minato-ku, Tokyo (JP); Masaya TOBA, Minato-ku, Tokyo (JP); Kazuyuki MITSUKURA, Minato-ku, Tokyo (JP)

(21) Appl. No.: 18/839,728

(22) PCT Filed: Feb. 22, 2022
(86) PCT No.: PCT/JP2022/007179

§ 371 Date: Oct. 10, 2024

(51) Int. Cl. H05K 1/03; H05K 3/00

(52) U.S. Cl. CPC H05K 1/0366; H05K 1/038; H05K 3/0055; H05K 2203/0228; H05K 2203/025; H05K 2203/06

(57) ABSTRACT

A method for producing a core substrate for wiring boards, which includes hot pressing an intermediate base material including a fiber base material and a thermosetting resin composition impregnated into the fiber base material, thereby forming a core substrate having a core portion having a first main surface and a second main surface on the rear side of the first main surface, the core portion including the fiber base material and an insulating resin layer that is the cured or semi-cured thermosetting resin composition; and planarizing at least one surface of the first main surface or the second main surface, thereby forming a flat surface.

### TECHNICAL FIELD

The present disclosure relates to a core substrate for wiring boards and a method for producing the same, and a wiring board and a method for producing the same.

### BACKGROUND ART

For the purpose of increasing the density and performance of semiconductor packages, a packaging form in which semiconductor chips that are different from one another in performance are mounted together in one package has been proposed. In such a packaging form, a technology for high density interconnect between chips that is excellent in terms of cost has been investigated (for example, see Patent Literature 1). In order to electrically connect the semiconductor chips mounted together at a high density, a wiring layer including fine wiring may be required.

### CITATION LIST

### Patent Literature

Patent Literature 1: Japanese Unexamined Patent Publication No. 2003-318519

### SUMMARY OF INVENTION

### Technical Problem

In a case of forming a wiring layer including fine wiring on a core substrate, for example, a semi-additive process is used in which a resist pattern including an opening is formed by exposing and developing a photosensitive resin layer provided on a core substrate and then wiring is formed by a plating method. However, minute waviness or irregularities on the core substrate surface may cause diffuse reflection, and this may decrease the accuracy of exposure. This phenomenon can be a factor of a decrease in yield, particularly in a case of forming fine wiring.

An aspect of the present disclosure relates to a core substrate that can be used to efficiently produce a wiring board having a wiring layer including fine wiring, and a method for producing the same.

### Solution to Problem

An aspect of the present disclosure relates to a method for producing a core substrate for wiring boards. The method comprises:

hot pressing an intermediate base material comprising a fiber base material and a thermosetting resin composition impregnated into the fiber base material, thereby forming a core substrate having a core portion having a first main surface and a second main surface on a rear side of the first main surface, the core portion comprising the fiber base material and an insulating resin layer that is the cured or semi-cured thermosetting resin composition; and planarizing at least one surface of the first main surface or the second main surface, thereby forming a flat surface.

Another aspect of the present disclosure relates to a method for producing a wiring board, the method comprising: preparing a core substrate having the flat surface by the method described above; and forming a wiring layer on the flat surface.

Still another aspect of the present disclosure relates to a core substrate for wiring boards comprising a fiber base material and an insulating resin layer impregnated into the fiber base material. The core substrate for wiring boards has a first main surface and a second main surface on the rear side of the first main surface. At least one of the first main surface or the second main surface is a flat surface having an arithmetic mean roughness Ra of 10 nm or less.

Still another aspect of the present disclosure relates to a wiring board comprising the core substrate for wiring boards described above; and a wiring layer provided on the flat surface.

### Advantageous Effects of Invention

The core substrate obtained by the method including planarizing a surface of a core substrate can afford a wiring board having a wiring layer including fine wiring at a high yield while maintaining high exposure accuracy. The fine wiring contributes to excellent transmission between semiconductor chips. Furthermore, the planarized surface of the core substrate also tends to reduce irregularities of the wiring layer, and this can contribute to the improvement in yield of semiconductor chip mounting on wiring boards.

### BRIEF DESCRIPTION OF DRAWINGS

FIG. 1 is a process drawing illustrating an example of a method for producing a core substrate.

FIG. 2 is a process drawing illustrating an example of a method for producing a core substrate.

FIG. 3 is a process drawing illustrating an example of a method for producing a core substrate.

FIG. 4 is a process drawing illustrating an example of a method for producing a core substrate.

### DESCRIPTION OF EMBODIMENTS

The present invention is not limited to the following examples.

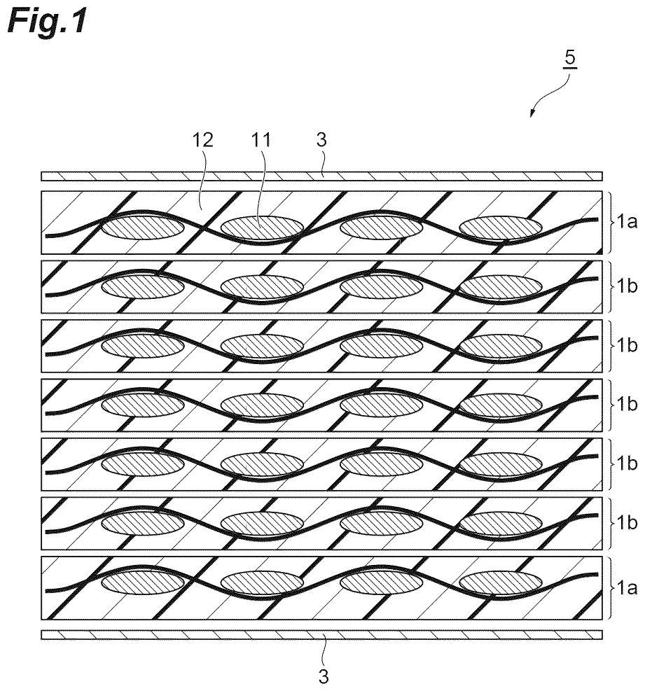

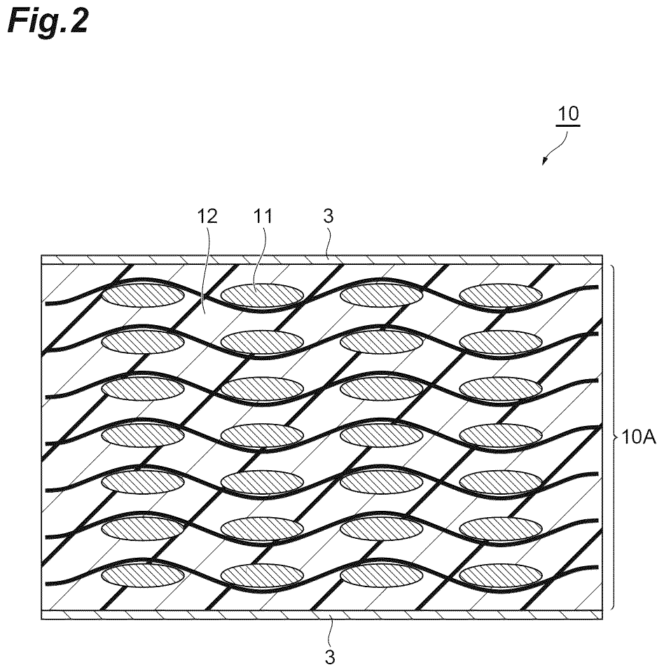

FIGS. 1, 2, 3, and 4 are process drawings illustrating an example of a method for producing a core substrate. The method illustrated in FIGS. 1, 2, 3, and 4 includes hot pressing an intermediate base material 5 including a fiber base material 11 and a thermosetting resin composition 12 impregnated into the fiber base material 11 to form a core substrate 10 having a core portion 10A with a first main surface 10S1 and a second main surface 10S2 on the rear side thereof; and planarizing at least one surface of the first main surface 10S1 or the second main surface 10S2 to form a flat surface FS. The core portion 10A includes the fiber base material 11 and an insulating resin layer 12 that is the cured thermosetting resin composition.

The intermediate base material 5 exemplified in FIG. 1 is composed of a laminate including a plurality of prepregs 1a and 1b each including the fiber base material 11 and the thermosetting resin composition 12; and a metal foil 3 disposed on both sides of this laminate. The number of prepregs constituting the intermediate base material 5 is not particularly limited and may be, for example, 1 or more and 20 or less. The fiber base material 11 and thermosetting resin composition 12 constituting the prepregs 1a and 1b will be described in detail later. The metal foil 3 can be selected from those commonly used in the application of wiring boards, and may be, for example, a copper foil or an aluminium foil.

In the prepreg 1a located in the outermost layer of the laminate, the fiber base material 11 does not need to be exposed to the surface. In other words, the fiber base material 11 may be disposed inside the layer of the thermosetting resin composition 12. This makes it possible to further reduce surface waviness of the core substrate caused by the fiber base material. It is also possible to easily form the flat surface FS while removing a part of the insulating resin layer formed from the thermosetting resin composition. From the same viewpoint, the minimum value of the distance between the fiber base material 11 and the outer surface of the prepreg 1a (the surface of the thermosetting resin composition 12) may be, for example, 1 μm or more and 5 μm or less or 1 μm or more and 2 μm or less.

The other prepreg 1b disposed inside the prepreg 1a may be the same as or different from the prepreg 1a. Similarly, the fiber base material 11 may be disposed inside the layer of the thermosetting resin composition 12 in the prepreg 1b as well.

The hot pressing for forming the core substrate 10 can be carried out by, for example, multi-stage pressing, multi-stage vacuum pressing, continuous molding, or autoclave molding. The conditions for hot pressing can be adjusted in the ranges of, for example, a temperature of 100° C. or more and 250° C. or less, a pressure of 2 kg/cm² or more and 100 kg/cm² or less, and a treatment time of 0.1 hours or more and 5 hours or less.

By hot pressing the intermediate base material 5, the core substrate 10 having the core portion 10A formed from a laminate of the prepregs 1a and 1b and the metal foil 3 laminated on both sides of the core portion 10A is formed. The core portion 10A includes the fiber base material 11 and the insulating resin layer 12 that is a cured or semi-cured thermosetting resin composition. The insulating resin layer 12 contains a thermosetting resin composition of which the curing reaction has progressed to a certain extent by hot pressing. The thermosetting resin composition constituting the insulating resin layer 12 is only required to be cured to an extent to which the surface of the insulating resin layer 12 can be planarized.

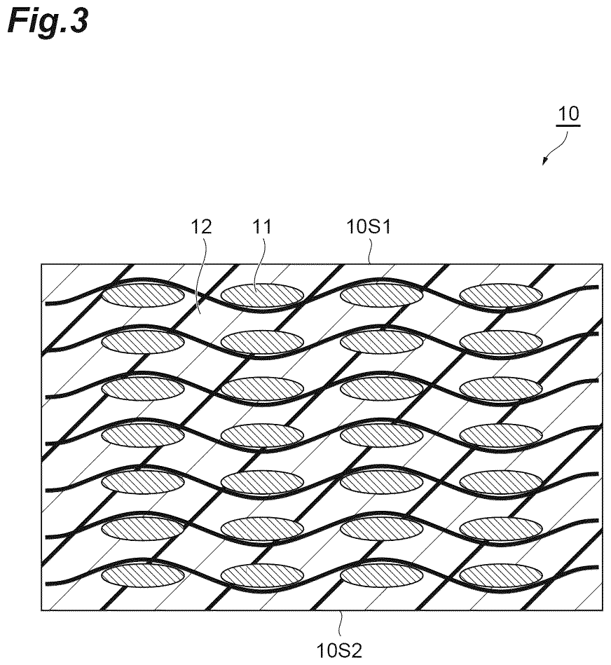

Subsequently, as illustrated in FIG. 3, the metal foil 3 is removed, and the first main surface 10S1 and second main surface 10S2 of the core substrate 10 (core portion) are thus exposed. The metal foil 3 can be removed by a common method.

In the core substrate 10 before the flat surface FS is formed, the fiber base material 11 does not need to be exposed on at least the surface to be planarized of the first main surface 10S1 or second main surface 10S2. In other words, the fiber base material 11 may be located in a region at a depth of 1 μm or more from the surface to be planarized of the first main surface 10S1 or the second main surface 10S2. The surface on which the fiber base material 11 is not exposed is formed by the insulating resin layer 12. The depth at which the fiber base material 11 is disposed, that is, the minimum value of the distance between the fiber base material 11 and the surface (the first main surface 10S1 or the second main surface 10S2) before being planarized may be, for example, 1 μm or more and 5 μm or less or 1 μm or more and 2 μm or less.

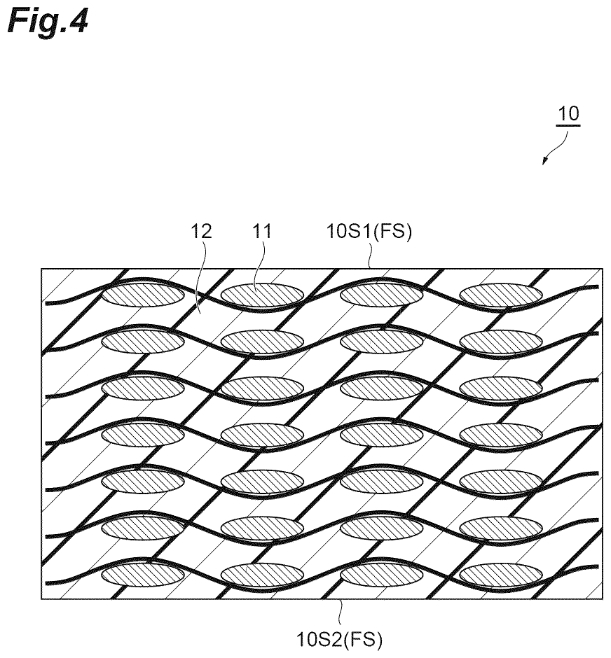

The flat surface FS is formed by planarizing at least one surface of the first main surface 10S1 or the second main surface 10S2 (FIG. 4). The planarization method can be, for example, a polishing method, a fly cutting method, or a combination thereof. The polishing method can be, for example, a mechanical polishing method or a chemical mechanical polishing method (CMP method). The fly cutting method is a method for planarizing the surface by removing a part of the surface layer portion of the core substrate 10 (mainly the insulating resin layer 12). The fly cutting method is carried out, for example, using a grinding attachment by diamond bit.

The flat surface FS formed by planarization can have an arithmetic mean roughness Ra of 10 nm or less. The arithmetic mean roughness Ra of the flat surface FS may be 1 nm or less or may be 0 nm or more. The arithmetic mean roughness Ra of the flat surface FS can be measured, for example, by a method of scanning the flat surface FS using a laser microscope.

A part of the insulating resin layer 12 is often removed during the planarization. After the flat surface FS is formed, the fiber base material 11 may be located inside the flat surface FS. This makes it possible to further reduce waviness of the flat surface FS caused by the fiber base material 11. In the core substrate 10 having the flat surface FS, the minimum value of the distance between the fiber base material 11 and the flat surface FS may be, for example, 1 μm or more and 5 μm or less or 1 μm or more and 2 μm or less.

The method for producing the core substrate may further include forming a modified region including minute voids in the insulating resin layer 12. There is a possibility that the flat surface FS hardly exhibits high close contact properties from the perspective of the anchor effect, but the close contact properties between the flat surface FS and the wiring provided on the flat surface FS can be improved as a modified region is provided. This is considered to be because a part of the metal constituting the wiring or a part of the metal constituting the seed layer for forming the wiring enters the voids in the modified region. At least a part of the voids in the modified region may communicate with the flat surface FS.

The method for forming the modified region may be at least one method selected from the group consisting of active energy ray irradiation, electron beam irradiation, ozone water treatment, and corona discharge treatment, or may be ultraviolet irradiation. The ultraviolet irradiation may be ultraviolet irradiation in which irradiation with ultraviolet rays from an incoherent light source is performed. An incoherent light source is advantageous in that a wide region of the insulating resin layer 12 can be efficiently irradiated with ultraviolet rays, for example, compared with a coherent light source such as a laser light source. Examples of the incoherent light source include a high pressure mercury lamp, a low pressure mercury lamp, and an excimer lamp. The incoherent light source may be a low pressure mercury lamp or an excimer lamp, which has a great activation effect.

The treatment (for example, ultraviolet irradiation) for forming the modified region can be carried out, for example, in air or in an oxygen atmosphere. In the treatment for forming the modified region, the temperature of the insulating resin layer 12 may be 25 to 100° C., 40 to 100° C., or 60 to 100° C. As the temperature is higher, the modified region can be more efficiently formed.

A wiring board including fine wiring can be produced at a high yield by a method including forming a wiring layer on the flat surface FS of the core substrate 10 prepared by the method exemplified above.

The wiring layer can include wirings that form a circuit pattern and an insulating layer provided between the wirings. The wiring layer may include, for example, formation of wiring by a semi-additive process, an additive process, or a subtractive process. A multi-layer wiring board may be obtained by laminating a plurality of core substrates and wiring layers interposed therebetween. A multi-layer wiring board can be produced by a method including laminating a plurality of core substrates and wiring layers and hot pressing the formed laminate. The method for producing a multi-layer wiring board may include forming through holes or blind via holes by drilling or laser processing after hot pressing; and forming interlayer wiring by plating or using a conductive paste.

The prepreg used to produce the core substrate can be produced, for example, by a method including impregnating or coating a fiber base material with a varnish that is a thermosetting resin composition containing a solvent and removing the solvent from the varnish. The fiber base material and varnish may be heated to remove the solvent from the varnish. The heating temperature may be 100 to 200° C. and the heating time may be 1 to 30 minutes. The thermosetting resin composition contained in the prepreg may have been semi-cured.

The fiber base material can include inorganic fibers, organic fibers, or a combination thereof. The inorganic fibers may be glass fibers, and examples thereof include E-glass fibers, D-glass fibers, S-glass fibers, and Q-glass fibers. Examples of the organic fibers include polyimide fibers, polyester fibers, and tetrafluoroethylene fibers. The surfaces of the fibers constituting the fiber base material may have undergone surface treatment with a silane coupling agent or the like.

The fiber base material may be, for example, one or more selected from a woven fabric, a nonwoven fabric, a roving, a chopped strand mat, or a surfacing mat. The thickness of the fiber base material may be, for example, 0.03 mm or more and 0.5 mm or less.

The thermosetting resin composition constituting the prepreg may contain, for example, (a) a maleimide compound having two or more N-substituted maleimide groups, (b) a silicone compound having an epoxy group, and (c) a compound having a phenolic hydroxyl group.

Examples of (a) the maleimide compound include bis(4-maleimidophenyl) methane, polyphenylmethane maleimide, bis(4-maleimidophenyl)ether, bis(4-maleimidophenyl)sulfone, 3,3′-dimethyl-5,5′-diethyl-4,4′-diphenylmethane bismaleimide, 4-methyl-1,3-phenylene bismaleimide, m-phenylene bismaleimide, and 2,2′-bis(4-(4-maleimidophenoxy)phenyl) propane. From the viewpoints of high reactivity and heat resistance, the maleimide compound may be one or more selected from bis(4-maleimidophenyl) methane, bis(4-maleimidophenyl) sulfone, 3,3′-dimethyl-5,5′-diethyl-4,4′-diphenylmethane bismaleimide, or 2,2′-bis(4-(4-maleimidophenoxy)phenyl) propane. From the viewpoint of solubility in a solvent, the maleimide compound may be 3,3′-dimethyl-5,5′-diethyl-4,4′-diphenylmethane bismaleimide, bis(4-maleimidophenyl) methane, or a combination thereof, or may be bis(4-maleimidophenyl) methane.

Examples of commercially available products of (b) the silicone compound having an epoxy group include “X-22-163” (functional group equivalent: 200), “KF-105” (functional group equivalent: 490), “X-22-163A” (functional group equivalent: 1000), “X-22-163B” (functional group equivalent: 1750), and “X-22-163C” (functional group equivalent: 2700), which are silicone compounds having a polysiloxane chain and epoxy groups bonded to both ends of the chain; “X-22-169AS” (functional group equivalent: 500) and “X-22-169B” (functional group equivalent: 1700), which are silicone compounds having a polysiloxane chain and alicyclic epoxy groups bonded to both ends of the chain; “X-22-1730X” (functional group equivalent: 4500), which is a silicone compound having a polysiloxane chain and an epoxy group bonded to one end of the chain; “X-22-9002” (functional group equivalent: 5000), which is a silicone compound having a polysiloxane chain and epoxy groups bonded to side chains and both ends of the chain; “X-22-343” (functional group equivalent: 525), “KF-101” (functional group equivalent 350), “KF-1001” (functional group equivalent 3500), “X-22-2000” (functional group equivalent 620), “X-22-4741” (functional group equivalent 2500) and “KF-1002” (functional group equivalent 4300), which are silicone compounds having a polysiloxane chain and an epoxy group bonded to side chains of the chain; and “X-22-2046” (functional group equivalent: 600) and “KF-102” (functional group equivalent: 3600), which are silicone compounds having a polysiloxane chain and an alicyclic epoxy resin bonded to side chains of the chain. These are used singly or in combination of two or more kinds thereof. From the viewpoint of heat resistance, the silicone compound having an epoxy group may be “X-22-163A”, “X-22-163B”, “X-22-343”, “X-22-9002”, or “KF-101”, or may be “X-22-163A” or “X-22-163B”. From the viewpoint of low coefficient of thermal expansion, the silicone compound having an epoxy group may be “X-22-163B”. The commercially available products exemplified here are all manufactured by Shin-Etsu Chemical Co., Ltd. The silicone compound having an epoxy group may be combined with various other epoxy resins.

The content of (b) the silicone compound having an epoxy group may be 20 parts by mass or more and 200 parts by mass or less or 50 parts by mass or more and 100 parts by mass or less with respect to 100 parts by mass of (a) the maleimide compound.

Examples of (c) the compound having a phenolic hydroxyl group include bisphenol A, bisphenol F, bisphenol S, 4,4′-biphenylphenol, tetramethyl bisphenol A, dimethyl bisphenol A, tetramethyl bisphenol F, dimethyl bisphenol F, tetramethyl bisphenol S, dimethyl bisphenol S, tetramethyl 4,4′-biphenol, dimethyl-4,4′-biphenylphenol, 1-(4-hydroxyphenyl)-2-[4-(1,1′-bis-(4-hydroxyphenyl)ethyl)phenyl]propane, 2,2′-methylene-bis(4-methyl-6-tert-butylphenol), 4,4′-butylidene-bis(3-methyl-6-tert-butylphenol), trishydroxyphenylmethane, resorcinol, hydroquinone, pyrogallol, a phenolic compound having a diisopropylidene skeleton, a phenolic compound having a fluorene skeleton (for example, 1,1′-di-4-hydroxyphenylfluorene), phenolized polybutadiene, and novolac resin. The novolac resin may be one formed from a phenol selected from phenol, cresols, ethylphenols, butylphenols, octylphenols, bisphenol A, bisphenol F, bisphenol S, or naphthols, or may be a xylylene skeleton-containing phenol novolac resin, a dicyclopentadiene skeleton-containing phenol novolac resin, a biphenyl skeleton-containing phenol novolac resin, or a fluorene skeleton-containing phenol novolac resin.

(c) The compound having a phenolic hydroxyl group may have an amino group, and examples thereof include m-aminophenol, p-aminophenol, o-aminophenol, p-aminobenzoic acid, m-aminobenzoic acid, o-aminobenzoic c acid, o-aminobenzenesulfonic acid, m-aminobenzenesulfonic acid, p-aminobenzenesulfonic acid, 3,5-dihydroxyaniline, and 3,5-dicarboxyaniline. These may be used singly or in combination of two or more kinds thereof. From the viewpoints of solubility and synthesis yield, the compound having a phenolic hydroxyl group and an amino group may be m-aminophenol, p-aminophenol, o-aminophenol, p-aminobenzoic acid, m-aminobenzoic acid or 3,5-dihydroxyaniline. From the viewpoint of heat resistance, the compound having a phenolic hydroxyl group and an amino group may be m-aminophenol or p-aminophenol. From the viewpoint of low thermal expansion properties, the compound having a phenolic hydroxyl group and an amino group may be p-aminophenol.

In the thermosetting resin composition, (a) the maleimide compound and (c) the compound having a phenolic hydroxyl group may have been reacted in advance. In this case, (c) the compound having a phenolic hydroxyl group may have an amino group or may be p-aminophenol. In a case where the component (c) is a compound having an amino group, the equivalent of the component (c) in terms of —NH₂ group and the maleimide group equivalent of (a) the maleimide compound may be in ranges that satisfy the following formula. 2.0≤(maleimide group equivalent)/(equivalent in terms of —NH₂ group)≤10.0

The thermosetting resin composition may contain a curing accelerator from the viewpoints of heat resistance, flame retardancy, adhesive properties to a metal foil, and the like. Examples of the curing accelerator include imidazole and derivatives thereof, tertiary amines, and quaternary ammonium salts.

From the viewpoints of heat resistance, flame retardancy, and adhesive properties to a metal foil, the curing accelerator may contain imidazole and/or a derivative thereof. From the viewpoints of curability at relatively low temperatures of 200° C. or less and time-dependent stability of the varnish or prepreg, the imidazole derivative may be a compound represented by the following Formula (1) or a compound represented by the following Formula (2).

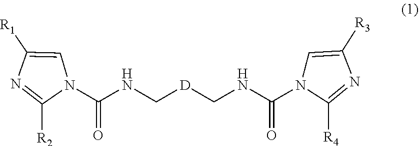

In Formula (1), R₁, R₂, R₃, and R₄ each independently represent a hydrogen atom, an aliphatic hydrocarbon group having 1 to 5 carbon atoms, or a phenyl group and D represents an alkylene group or an aromatic hydrocarbon group.

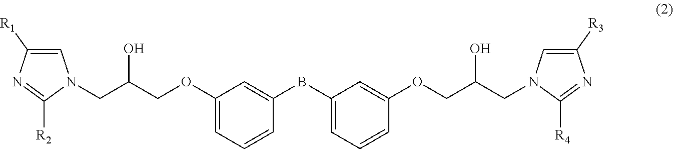

In Formula (2), R₁, R₂, R₃, and R₄ each independently represent a hydrogen atom, an aliphatic hydrocarbon group having 1 to 5 carbon atoms, or a phenyl group and B represents a single bond, an alkylene group, an alkylidene group, an oxy group, or a sulfonyl group.

The imidazole derivative may be a compound represented by the following Formula (3) or (4).

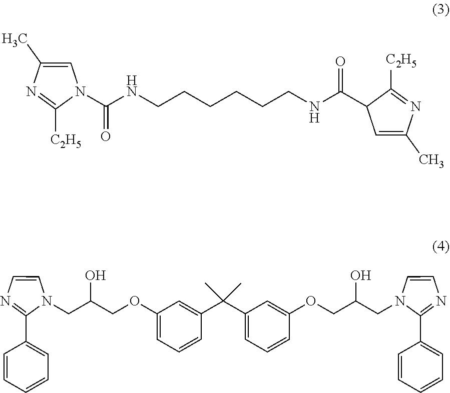

The content of the curing accelerator may be 0.1 parts by mass or more and 10 parts by mass or less, 0.1 parts by mass or more and 5 parts by mass or less, or 0.1 parts by mass or more and 1 part by mass or less with respect to 100 parts by mass of the total content of (a) the maleimide compound, (b) the silicone compound having an epoxy group, and (c) the compound having a phenolic hydroxyl group.

The thermosetting resin composition may contain an inorganic filler. Examples of the inorganic filler include silica, alumina, talc, mica, kaolin, aluminium hydroxide, boehmite, magnesium hydroxide, zinc borate, zinc stannate, zinc oxide, titanium oxide, boron nitride, calcium carbonate, barium sulfate, aluminium borate, potassium titanate, and inorganic glass particles. The inorganic glass particles may be hollow particles. The glass constituting the inorganic glass particles may be E-glass, T-glass, or D-glass. These can be used singly or in combination of two or more kinds thereof. From the viewpoints of dielectric properties, heat resistance, and low thermal expansion properties, the inorganic filler may be silica. The silica may be, for example, precipitated silica or silica by dry process. The silica by dry process may be, for example, crushed silica, fumed silica, or fused spherical silica. From the viewpoints of low thermal expansion properties and flowability of the thermosetting resin composition, the inorganic filler may be fused spherical silica. The average particle size of the fused spherical silica may be 0.1 μm or more and 10 μm or less or 0.3 μm or more and 8 μm or less. The average particle size refers to a particle size that corresponds to the volume of 50% when a cumulative frequency distribution curve by the particle size is determined assuming the total volume of particles to be 100%. The average particle size can be measured using a particle size distribution measuring instrument by a laser diffraction scattering method.

The content of the inorganic filler may be 10 parts by mass or more and 70 parts by mass or less or 30 parts by mass or more and 55 parts by mass or less with respect to 100 parts by mass of the total content of (a) the maleimide compound, (b) the silicone compound having an epoxy group, and (c) the compound having a phenolic hydroxyl group.

The thermosetting resin composition may contain another thermosetting resin, and examples thereof include an epoxy resin, a phenolic resin, an unsaturated imide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin. These can be used singly or in combination of two or more kinds thereof. From the viewpoints of moldability and electric insulation, the other thermosetting resin may be an epoxy resin or a cyanate resin.

Examples of the epoxy resin include a bisphenol A type epoxy resin, a bisphenol F type epoxy resin, a bisphenol S type epoxy resin, a phenol novolac type epoxy resin, a cresol novolac type epoxy resin, a bisphenol A novolac type epoxy resin, a bisphenol F novolac type epoxy resin, a stilbene type epoxy resin, a triazine skeleton-containing epoxy resin, a fluorene skeleton-containing epoxy resin, a triphenol phenol methane type epoxy resin, a biphenyl type epoxy resin, a xylylene type epoxy resin, a biphenyl aralkyl type epoxy resin, a naphthalene type epoxy resin, a dicyclopentadiene type epoxy resin, an alicyclic epoxy resin, diglycidyl ether compounds of polycyclic aromatics (for example, polyfunctional phenols and anthracene), and phosphorus-containing epoxy resins obtained by introducing phosphorus compounds into these. From the viewpoints of heat resistance and flame retardancy, the epoxy resin may be a biphenyl aralkyl type epoxy resin or a naphthalene type epoxy resin. These can be used singly or in combination of two or more kinds thereof.

Examples of the cyanate resin include a novolac type cyanate resin, bisphenol type cyanate resins such as a bisphenol A type cyanate resin, a bisphenol E type cyanate resin, and a tetramethyl bisphenol F type cyanate resin, and prepolymers of these partly triazined. From the viewpoint of flame retardancy, the cyanate resin may be a novolac type cyanate resin. These can be used singly or in combination of two or more kinds thereof.

The thermosetting resin composition may further contain other components of a thermoplastic resin, an elastomer, a flame retardant, and an organic filler.

Examples of the thermoplastic resin include tetrafluoroethylene, polyethylene, polypropylene, polystyrene, a polyphenylene ether resin, a phenoxy resin, a polycarbonate resin, a polyester resin, a polyamide resin, a polyimide resin, a xylene resin, a petroleum resin and a silicone resin.

Examples of the elastomer include polybutadiene, acrylonitrile, epoxy-modified polybutadiene, maleic anhydride-modified polybutadiene, phenol-modified polybutadiene and carboxy-modified acrylonitrile.

Examples of the flame retardant include halogen-based flame retardants containing bromine or chlorine, phosphorus-based flame retardants (for example, triphenyl phosphate, tricresyl phosphate, trisdichloropropyl phosphate, a phosphate ester-based compound, and red phosphorus), nitrogen-based flame retardants (for example, guanidine sulfamate, melamine sulfate, melamine polyphosphate, and melamine cyanurate), phosphazene-based flame retardants (for example, cyclophosphazene and polyphosphazene), and inorganic flame retardants (for example, antimony trioxide).

The thermosetting resin composition may further contain, optionally, other components selected from ultraviolet absorbers (for example, benzotriazoles), antioxidants (for example, hindered phenol-based ones and styrenated phenol), photopolymerization initiators (for example, benzophenones, benzil ketals, and thioxanthone-based ones), fluorescent whitening agents (for example, stilbene derivatives) or close contact property improvers (for example, silane coupling agents).

Examples of the solvent used to form the varnish include alcohol-based solvents such as ethanol, propanol, butanol, methyl cellosolve, butyl cellosolve, and propylene glycol monomethyl ether; ketone-based solvents such as acetone, methyl ethyl ketone, methyl isobutyl ketone, and cyclohexanone; ether-based solvents such as tetrahydrofuran; aromatic solvents such as toluene, xylene, and mesitylene; nitrogen atom-containing solvents such as dimethylformamide, dimethylacetamide, and N-methylpyrrolidone; and sulfur atom-containing solvents such as dimethyl sulfoxide. These can be used singly or in combination of two or more kinds thereof.

### REFERENCE SIGNS LIST

1a, 1b: prepreg, 3: metal foil, 5: intermediate base material, 10: core substrate, 10A: core portion, 10S1: first main surface, 10S2: second main surface, 11: fiber base material, 12: thermosetting resin composition or insulating resin layer, FS: flat surface.

1. A method for producing a core substrate for wiring boards, the method comprising:
hot pressing an intermediate base material comprising a fiber base material and a thermosetting resin composition impregnated into the fiber base material, thereby forming a core substrate having a core portion having a first main surface and a second main surface on a rear side of the first main surface, the core portion comprising the fiber base material and an insulating resin layer that is the cured or semi-cured thermosetting resin composition; and
planarizing at least one surface of the first main surface or the second main surface, thereby forming a flat surface.

2. The method according to claim 1, wherein the flat surface having an arithmetic mean roughness Ra of 10 nm or less is formed by planarizing at least one surface of the first main surface or the second main surface.

3. The method according to claim 1, wherein at least one surface of the first main surface or the second main surface is planarized by a polishing method, a fly cutting method, or a combination thereof.

4. The method according to claim 1, wherein the fiber base material is located beneath the flat surface.

5. The method according to claim 1, wherein, in the core substrate before the flat surface is formed, the fiber base material is located in a region at a depth of 1 μm or more from a surface to be planarized of the first main surface or second main surface.

6. The method according to claim 1, further comprising forming a modified region including a void in the insulating resin layer.

7. A method for producing a wiring board, the method comprising:
preparing a core substrate having the flat surface by the method according to claim 1; and
forming a wiring layer on the flat surface.

8. A core substrate for wiring boards comprising:
a fiber base material; and
an insulating resin layer impregnated into the fiber base material, wherein
the core substrate for wiring boards has a first main surface and a second main surface on a rear side of the first main surface; and
at least one of the first main surface or the second main surface is a flat surface having an arithmetic mean roughness Ra of 10 nm or less.

9. The core substrate for wiring boards according to claim 8, wherein the insulating resin layer has a modified region including a void, which is provided in a surface layer portion on a flat surface side of the core substrate.

10. A wiring board comprising:
the core substrate for wiring boards according to claim 8; and
a wiring layer provided on the flat surface.
